(19) United States
(12) Patent Application Publication
(10) Pub. No.: US 2025/0160073 A1
(43) Pub. Date: May 15, 2025

(54) SEMICONDUCTOR LIGHT EMITTING DEVICE AND METHOD OF MANUFACTURING THE SAME

(71) Applicant: Stanley Electric Co., Ltd., Tokyo (JP)

(72) Inventor: Ji-Hao LIANG, Tokyo (JP)

(73) Assignee: Stanley Electric Co., Ltd., Tokyo (JP)

(21) Appl. No.: 18/941,213

(22) Filed: Nov. 8, 2024

(30) Foreign Application Priority Data
Nov. 10, 2023 (JP) 2023-192442

(51) Int. Cl. H01L 33/50; H01L 33/00; H01L 33/32

(52) U.S. Cl. CPC H10H 20/8515; H10H 20/01; H10H 20/825; H10H 20/8512; H10H 20/0361

(57) ABSTRACT

Provided is a semiconductor light emitting device capable of performing bonding of a phosphor plate and a light emitting element in the atmosphere by surface activated bonding. A semiconductor light emitting device includes a light emitting element including a semiconductor light emitting layer, and a phosphor plate bonded to the light emitting element. A buffer layer formed of a dielectric that transmits light emitted by the light emitting element is disposed between the light emitting element and the phosphor plate. The light emitting element and the phosphor plate are bonded with the buffer layer interposed therebetween. The buffer layer is amorphous.

### CROSS-REFERENCE TO RELATED APPLICATION

This application claims the priority benefit to Japanese Patent Application No. JP2023-192442 filed on Nov. 10, 2023, which is disclosed hereby in its entirety by reference.

### BACKGROUND OF THE INVENTION

### 1. Field of the Invention

The present invention relates to a semiconductor light emitting device that has a structure in which a semiconductor light emitting element and a phosphor plate are directly bonded without involving a resin adhesive layer or the like.

### 2. Description of Related Art

PTL 1, PTL 2, or the like disclose methods of manufacturing light emitting devices in which phosphor plates are mounted on light emitting elements by directly bonding by surface activated bonding (SAB) without using adhesives. Since light emitting devices manufactured by such manufacturing methods do not include adhesive layers with refractive indices different from light emitting elements or phosphor plates (in particular, adhesive layers with refractive indices lower than light emitting elements or phosphor plates), light extraction efficiency from the light emitting devices is improved.

Specifically, according to a manufacturing method of PTL 1, segmented light emitting elements are arranged on a relay substrate, each bonding surface of the light emitting elements and phosphor ceramics are polished, and then the light emitting elements and the phosphor ceramics are disposed in a vacuum apparatus. In the vacuum apparatus, after each bonding surface is irradiated with an ion beam of a noble gas element (at least one of He, Ne, Ar, and Kr), the bonding surfaces are brought into contact with each other and pressurized for bonding. After the bonded light emitting elements and the phosphor ceramics are extracted from the vacuum apparatus, the phosphor ceramics are cut and segmented by dicing for each light emitting device.

On the other hand, PTL 2 discloses a method of manufacturing an individual light emitting device by directly bonding a substrate of a light emitting element to a phosphor plate by surface activated bonding, and then cleaving both the light emitting element and the phosphor plate for each light emitting device. According to such manufacturing method, an element substrate on which a plurality of light emitting elements are formed is bonded to the phosphor plate by surface activated bonding. Before the bonding, the element substrate is thinned by a grinding or polishing scheme and cracks are formed in advance by radiating laser light to a position of a boundary between elements of the thinned element substrate. The bonding is performed by surface activated bonding by bringing the phosphor plate into contact with the element substrate in which the cracks are formed and performing pressurization. Thereafter, the phosphor plate is cut partway in a thickness direction of the phosphor plate by a blade. Segmentation is achieved by pressurizing a position of the boundary between elements from the light emitting element side and cleaving the element substrate by the cracks while simultaneously cleaving portions in which a semiconductor structure or a wiring structure of the light emitting element in which the cracks are not formed and portions of the phosphor plate that are not cut.

### CITATION LIST

### Patent Literature

PTL 1: JP2019-220675A
PTL 2: JP2021-197542A

### SUMMARY OF THE INVENTION

In the manufacturing method of PTL 1, the bonding surfaces of the light emitting element and the phosphor ceramic are irradiated with an ion beam of a noble gas element for surface processing. Therefore, it is necessary to dispose the light emitting element and the phosphor ceramic in the vacuum apparatus. After the irradiation of the ion beam, the vacuum apparatus is not opened to the atmosphere and the bonding surfaces of the light emitting element and the phosphor ceramic are brought into contact with each other for bonding in vacuum. Therefore, it is necessary to perform all operations such as a surface activation process, alignment, substrate heating, and substrate weighting in vacuum, which complicates a device configuration and makes the device expensive, and therefore causes an increase in cost of product.

According to the manufacturing method of PTL 1, after the light emitting elements are segmented and arranged in advance and the phosphor ceramics are bonded on the light emitting elements by surface activated bonding, the phosphor ceramics are cut and segmented for each individual light emitting device. Therefore, in the segmented light emitting device, there is a problem that the size of the phosphor ceramic is necessarily larger than that of the light emitting element.

Meanwhile, according to the manufacturing method of PTL 2, the light emitting element is not segmented in advance. Since cracks are introduced in advance into the element substrate by laser light so that the element substrate can be cleaved later, the strength of the element substrate deteriorates. Therefore, when the phosphor plate is brought into contact with the element substrate and is bonded by surface activated bonding, it is necessary to limit a weight for pressurization to prevent the element substrate from cracking.

In a step after the element substrate and the phosphor plate are bonded, there is concern of the element substrate being cracked due to internal stress, external stress, or the like. When the element substrate is curved or an external force is applied, the element substrate and the phosphor plate are likely to be delaminated on the bonding surfaces.

An object of the present invention is to provide a semiconductor light emitting device with high bonding reliability between the phosphor plate and the light emitting element by surface activated bonding.

To achieve the above object, a semiconductor light emitting device according to an aspect of the present invention includes a light emitting element including a semiconductor light emitting layer, and a phosphor plate bonded to the light emitting element. A buffer layer formed of a dielectric that transmits light emitted by the light emitting element is disposed between the light emitting element and the phosphor plate. The light emitting element and the phosphor plate are bonded with the buffer layer interposed therebetween. The buffer layer is amorphous.

According to the semiconductor light emitting device according to the aspect of the present invention, it is possible to improve bonding reliability between the phosphor plate and the light emitting element by surface activated bonding.

### BRIEF DESCRIPTION OF THE DRAWINGS

FIGS. 1A and 1B are a sectional view and a top view illustrating a semiconductor light emitting device according to a first embodiment;

FIGS. 2A to 2G are diagrams illustrating steps of manufacturing the semiconductor light emitting device according to the first embodiment;

FIGS. 3A to 3E are diagrams illustrating steps of manufacturing the semiconductor light emitting device according to the first embodiment;

FIG. 4 is a sectional view illustrating a shape of a stacked body after the manufacturing step of FIG. 3C;

FIGS. 5A to 5E are diagrams illustrating examples of cross-sectional shapes of slits formed in the step of FIG. 3B according to the first embodiment;

FIGS. 6A and 6B are a sectional view and a top view illustrating a semiconductor light emitting device according to a modified example of the first embodiment;

FIG. 7 is a sectional view illustrating a semiconductor light emitting device according to a second embodiment;

FIGS. 8A to 8G are diagrams illustrating steps of manufacturing the semiconductor light emitting device according to the second embodiment;

FIGS. 9A to 9E are diagrams illustrating steps of manufacturing the semiconductor light emitting device according to the second embodiment;

FIGS. 10A to 10J are diagrams illustrating steps of manufacturing the semiconductor light emitting device according to a third embodiment;

FIG. 11 is a sectional view illustrating a semiconductor light emitting device according to a fourth embodiment;

FIGS. 12A to 12I are diagrams illustrating steps of manufacturing the semiconductor light emitting device according to the fourth embodiment; and

FIGS. 13H-1, 13H-2, and 13I are diagrams illustrating steps of manufacturing the semiconductor light emitting device according to the fourth embodiment.

### DESCRIPTION OF EMBODIMENTS

Embodiments of the present invention will be described below.

### First Embodiment

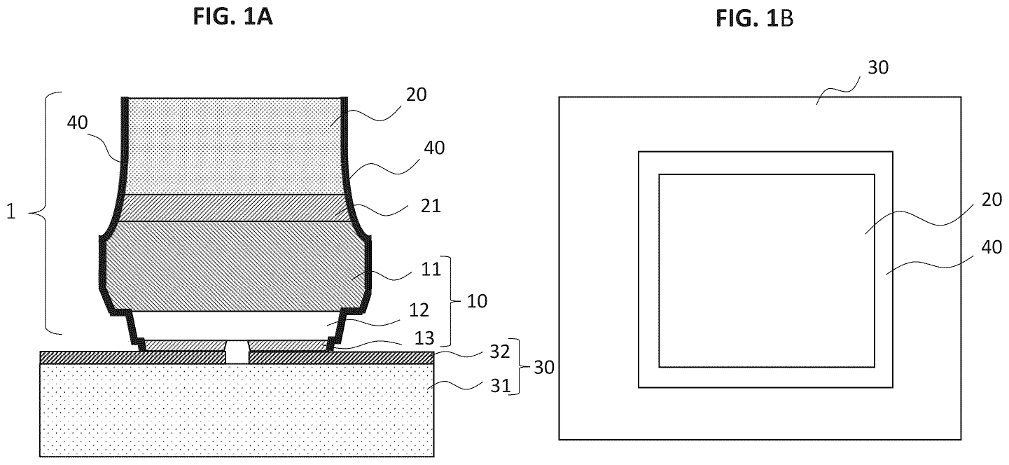

A semiconductor light emitting device according to a first embodiment will be described with reference to FIGS. 1A to 4. FIGS. 1A and 1B are a sectional view and a top view illustrating a semiconductor light emitting device 1 according to the first embodiment.

As in FIG. 1A, the semiconductor light emitting device 1 according to the embodiment has a structure in which a phosphor plate 20 is bonded on an upper surface of a light emitting element 10 by surface activated bonding (SAB). In the semiconductor light emitting device 1 in FIG. 1A, the light emitting element 10 is a flip-chip type light emitting element. The light emitting element 10 includes a semiconductor light emitting layer 12, an element substrate 11 disposed on an upper surface of the semiconductor light emitting layer 12, and a pair of electrodes 13 disposed on a lower surface of the semiconductor light emitting layer 12. The phosphor plate 20 is bonded on an upper surface of the element substrate 11.

A buffer layer 21 is disposed on a bonding surface of the element substrate 11 and the phosphor plate 20. A part of side surfaces of the light emitting element 10, the buffer layer 21, and the phosphor plate 20 is formed by dicing and the other parts of the side surfaces are formed by cleaving, such that the side surfaces are smooth without an acute angle and covered with a photo-reflective multi-layered film 40. The photo-reflective multi-layered film 40 may not be provided. The side surfaces may be covered with photo-reflective resin instead of forming the photo-reflective multi-layered film 40.

In the example of FIGS. 1A and 1B, the semiconductor light emitting device 1 is mounted on a wiring substrate 30 including a pair of wirings 32 and a substrate 31. The pair of electrodes 13 of the light emitting element 10 are electrically connected to the pair of wirings 32.

For example, as the light emitting element 10, a blue LED in which the element substrate 11 is one of a sapphire substrate, a spinel substrate, and a GaN substrate and the semiconductor light emitting layer 12 includes a GaN layer can be used.

The phosphor plate 20 absorbs part of light emitted from the semiconductor light emitting layer 12 and generates fluorescent light with a predetermined wavelength, thereby converting a wavelength of light emitted from the semiconductor light emitting layer 12 and outputting the converted light from an upper surface.

The phosphor plate 20 is, for example, formed by a composite ceramic phosphor plate (Al₂O₃/Ce:YAG) in which Ce-doped YAG (Y₃Al₅O₁₂) phosphor particles are dispersed in a ceramic matrix of alumina. The phosphor plate 20 is not limited to the composite ceramic phosphor plate (Al₂O₃/Ce:YAG), and a phosphor plate formed of a single crystal of Ce:YAG, a phosphor ceramic plate with a YAG matrix (YAG/Ce:YAG), or glass can be used. In the composite ceramic phosphor plate, a particle size and density of YAG particles can also be appropriately selected according to a use purpose.

The surface activated bonding is bonding by an intermolecular force of substances of both sides of the bonding surface, and it is necessary to set a spacing between molecules of substances of both sides of the bonding surface to a distance in which the intermolecular force acts (about 0.5 nm or less). Therefore, to bond the phosphor plate 20 and the element substrate 11 by the surface activated bonding, it is necessary to flatten the surfaces of the phosphor plate 20 and the element substrate 11 up to roughness of a distance in which the intermolecular force acts (about 0.5 nm or less) or less.

The composite ceramic phosphor plate that configures the phosphor plate 20 is configured of fine crystal grains, and hardness is different between fine crystal grains of a ceramic matrix and fine crystal grains of a phosphor. The hardness of the fine crystal grains differs according to a direction in which a crystal axis of the fine crystals is oriented in the phosphor plate 20. Therefore, even when the phosphor plate 20 is polished, surface unevenness (roughness) of about 1/20 of a grain size of abrasive particles of a slurry used for polishing remains.

Specifically, for example, in the case of the phosphor plate 20 formed by the composite ceramic phosphor plate (Al₂O₃/Ce:YAG), when mirror-polishing is performed with a slurry including diamond particles of 1 μm as polishing particles, unevenness of about 50 nm remains at a boundary of the crystal grains due to the difference in the hardness of Al₂O₃ and YAG. A Ce:YAG phosphor plate with a YAG matrix (a plate in which Ce-doped YAG phosphor particles are disposed in a YAG ceramic matrix) is a ceramic in which phosphor particles have the same chemical formula as the matrix, but due to presence of fine crystal grains, even when polishing is performed with a slurry including diamond particles with a grain size of 50 nm as polishing particles by chemical mechanical polishing (CMP), a surface unevenness of about ±2 nm (roughness Ra about 1.5 nm) remains. Therefore, it is difficult to flatten the surface of the phosphor plate 20 up to roughness of a distance in which an intermolecular force acts (about 0.5 nm or less) or less.

Accordingly, in the embodiment, the buffer layer 21 is disposed between the phosphor plate 20 and the light emitting element 10. The buffer layer 21 is an amorphous layer of a dielectric. The amorphous layer can be flattened up to roughness of a distance in which an intermolecular force acts (about 0.5 nm or less) or less by polishing or the like. Accordingly, by disposing the amorphous buffer layer 21 on at least the lower surface of the phosphor plate 20, it is possible to easily bond the phosphor plate 20 to the light emitting element 10 by the surface activated bonding.

The buffer layer 21 of the amorphous layer may be provided on both the upper surface of the element substrate 11 and the lower surface of the phosphor plate 20. The buffer layer 21 may be provided only in the element substrate 11.

The amorphous buffer layer 21 mentioned here is a layer that does not show a diffraction peak in an X-ray diffraction chart when X-ray diffraction is measured. Here, the amorphous buffer layer 21 does not show a crystal-derived diffraction peak in X-ray diffraction in principle, but a peak caused by fine crystal grains occurring on the interface with an underlayer at the time of forming the buffer layer 21 is permitted. Even then, a volume ratio of an amorphous phase in the amorphous buffer layer 21 to the entire layer is preferably 90% or more.

The buffer layer 21 preferably transmits light emitted by the light emitting element 10 and preferably does not absorb light in the entire white spectrum.

The buffer layer 21 may be formed of any material as long as the material is an inorganic material in which a thermal expansion coefficient and a refractive index are close to those of the phosphor plate 20 and the light emitting element 10 to be bonded, thermal conductivity is good when made into a thin film, acid-alkali resistance is good, a stress corrosion property is low, and flattening can be performed up to roughness of a distance in which an intermolecular force acts (about 0.5 nm or less) or less by polishing or the like. The buffer layer 21 preferably has a relatively high Young's modulus (hardness).

For example, for the buffer layer 21, an inorganic transparent dielectric material such as an oxide containing Al (aluminum oxide, Al₂O₃, or the like), silicon oxide (SiO₂ or the like), niobium oxide (Nb₂O₅ or the like), tantalum oxide (Ta₂O₅ or the like), titanium oxide (TiO₂ or the like), yttrium oxide (Y₂O₃ or the like), magnesium oxide (MgO or the like), and zirconium oxide (ZrO₂ or the like) can be appropriately used. In particular, an oxide containing Al (Al₂O₃ or the like) is appropriate for the buffer layer 21 in that a thermal expansion coefficient and a refractive index are close to those of the phosphor plate 20 and the light emitting element 10, thermal conductivity is good when made into a thin film, and a corrosion property is low.

It is preferable for the thermal expansion coefficient of the buffer layer 21 to be close to thermal expansion coefficients of members to be bonded because a large difference in the thermal expansion coefficient between the buffer layer and the members to be bonded result in significant strain when returning to room temperature after bonding. Since a difference in the thermal expansion coefficient between the members to be bonded and the aluminum oxide (Al₂O₃ or the like) is smaller than that between the members to be bonded and the silicon oxide (SiO₂ or the like), a bonding strain is small in a use environment and resistance to a change in an environmental temperature (thermal shock) of a bonding portion is higher.

The thermal expansion coefficient of the buffer layer 21 is preferably higher because heat emitted from the phosphor plate 20 is better radiated to the outside via the light emitting element 10 and a mounting substrate. The aluminum oxide (Al₂O₃ or the like) has a higher thermal expansion coefficient than the silicon oxide (SiO₂ or the like), and a higher heat dissipation effect can be expected.

The refractive index of the buffer layer 21 is preferably close to a refractive index of the element substrate 11 or greater than the refractive index of the element substrate 11. Blue light emitted from the light emitting element 10 is incident on the phosphor plate 20 via the element substrate 11 (for example, a sapphire substrate with a refractive index of 1.76). Here, when the buffer layer 21 interposed between the element substrate 11 and the phosphor plate 20 has a low refractive index, a light beam incident on an interface between the element substrate 11 and the buffer layer 21 at a large angle of incidence is totally reflected and is trapped in the element substrate 11. Accordingly, it is advantageous for the refractive index of the buffer layer 21 to be as close as possible to the refractive index of the element substrate 11 or larger than the refractive index of the element substrate 11 in that light extraction is better. Al₂O₃ (refractive index of 1.64) has a refractive index closer to that of the element substrate 11 than SiO₂ (refractive index of 1.46). When Al₂O₃ is used as the buffer layer 21, light extraction efficiency can be higher.

The buffer layer 21 preferably has a relatively high Young's modulus (hardness), because there is concern of the buffer layer 21 itself being broken when the Young's modulus is too low. For example, the Young's modulus is preferably about 50 GPa or higher. It is better that the Young's modulus is higher if the surface flatness is satisfied. As Al₂O₃ has a higher Young's modulus than SiO₂ (Al₂O₃ has 112 GPa and SiO₂ has 50 GPa), when Al₂O₃ is used as the buffer layer 21, high bonding reliability can be obtained.

When aluminum oxide (Al₂O₃ or the like) is used as a material of the buffer layer 21 and a composite ceramic phosphor plate (Al₂O₃/Ce:YAG) in which Ce-doped YAG phosphor particles are dispersed in an alumina ceramic matrix is used as the phosphor plate 20, the material of the buffer layer 21 is Al₂O₃ that is the same as a matrix of the phosphor plate 20. Therefore, the effect that the bonding strength in the interface is high can also be obtained. That is, in a region where the matrix of the phosphor plate 20 and the buffer layer 21 come into contact with each other, homogeneous bonding is achieved, and as the thermal expansion coefficient is nearly the same, there is less residual stress after the bonding and stable bonding can be achieved.

When aluminum oxide (Al₂O₃ or the like) is used as the material of the buffer layer 21 and sapphire (Al₂O₃) substrate is used as the element substrate 11, homogeneous bonding is achieved, and as the thermal expansion coefficient is nearly the same, there is nearly less residual stress after the bonding and stable bonding can be achieved.

Accordingly, the element substrate 11, the buffer layer 21, and the phosphor plate 20 can be stably bonded by homogeneous bonding.

A thickness of the amorphous buffer layer 21 may be a thickness in which unevenness of the phosphor plate 20 or the light emitting element 10 is covered and the surface of the buffer layer 21 can be flattened up to roughness of a distance in which an intermolecular force acts (about 0.5 nm or less) or less by polishing or the like. Specifically, the thickness of the buffer layer 21 is preferably in the range of, for example, 50 nm to 2 μm and is particularly in the range of about 200 nm to 600 nm.

The amorphous buffer layer 21 can be formed by a vapor deposition method of, for example, a physical vapor deposition method such as an electron beam (EB) evaporation method of heating a material with an electron beam or a sputtering method, a chemical vapor deposition (CVD) method, or an atomic layer deposition (ALD) method. In particular, it is preferable to form the buffer layer 21 by a physical vapor deposition method without using substrate heating as far as possible. In particular, an EB evaporation method is appropriate because the amorphous buffer layer 21 can be easily formed without adjusting a substrate temperature during formation.

When polishing the surfaces of the amorphous buffer layer 21, the phosphor plate 20, and the light emitting element 10, a CMP method can be used. In the CMP method, a nano-slurry (diamond, silica, or alumina) having a particle diameter of a few nm to tens of nm is used.

Specifically, for example, the phosphor plate 20 is polished with a chemical mechanical polishing (CMP) method with a slurry including diamond particles as polishing particles having a grain size of 50 nm, a polished surface is further etched finely as necessary, an organic contaminant is removed from the surface, ultraviolet (for example, excimer light) treatment and plasma treatment are applied to activate the bonding surfaces (to cut bonds of the surface molecules and form dangling bonds), and then the buffer layer 21 is formed by a physical vapor deposition (EB, sputtering) method or a vapor deposition method (ALD or CVD).

The surface of the buffer layer 21 has an uneven shape due to unevenness of the polished surface of the phosphor plate 20 immediately after the formation. By polishing the buffer layer 21 by the CMP method, it is possible to flatten up to the roughness of a distance in which an intermolecular force acts (about 0.5 nm or less) or less.

The CMP polishing for the buffer layer 21 is performed using, for example, a surface table on which a buff with relatively low hardness is mounted and a silica-based slurry.

By using the amorphous buffer layer 21, compared to the case in which the buffer layer 21 is formed of single crystal, the hardness is lower and the buffer layer 21 has flexibility when the phosphor plate 20 including the buffer layer 21 is brought into contact with the element substrate 11. Accordingly, by applying pressurization, it is possible to plastically deform the buffer layer 21 to come into close contact with the surface shape of the element substrate 11. Therefore, it is possible to easily perform the surface activated bonding.

The buffer layer 21 preferably includes no cavity (void). When the buffer layer 21 includes a void, the surface flatness of the buffer layer 21 may deteriorate, which causes a decrease in bonding strength of the surface activated bonding.

In the embodiment, when the semiconductor light emitting device 1 is manufactured, the large phosphor plate 20 to form continuous phosphor plates 20 for a plurality of semiconductor devices 1 is bonded on the large element substrate 11 configured so that the plurality of light emitting elements 10 are continuously arranged, and a stacked body is formed. To divide the stacked body at positions of boundaries of the plurality of semiconductor light emitting devices 1 and obtain the individual semiconductor light emitting devices 1, incisions are formed on the stacked body from the phosphor plate 20 side by dicing or the like and notches are formed from the light emitting layer 12 side of the element substrate 11.

Here, the incisions are formed to penetrate through the buffer layer 21. Specifically, the incisions are formed to penetrate through the buffer layer 21 and reach the element substrate 11. That is, the incisions are formed to penetrate through the bonding surface of the phosphor plate 20 and a light emitting element plate 100 (in the embodiment, an interface between the buffer layer 21 and the element substrate 11) and reach the light emitting element plate 100 (here, the element substrate 11).

Accordingly, internal stress of the bonding surface of the phosphor plate 20 and the element substrate 11 is released, stress is prevented from focusing on the bonding surface when a force is received from the outside, and thus the phosphor plate and the element substrate 11 are prevented from peeling off from the bonding surface. Accordingly, a manufacturing yield is improved.

When the buffer layer 21 is provided on both the phosphor plate 20 and the element substrate 11, an interface between a first buffer layer on the phosphor plate 20 side and a second buffer layer on the element substrate 11 side becomes a bonding interface. Therefore, the incision is formed to penetrate through at least the first buffer layer and penetrate through the bonding surface.

When the buffer layer 21 is provided only on the element substrate 11 side, the interface between the buffer layer 21 and the phosphor plate 20 becomes a bonding surface. Therefore, the incision is formed to penetrate through at least the phosphor plate 20 and penetrate through the bonding surface.

### Manufacturing Method

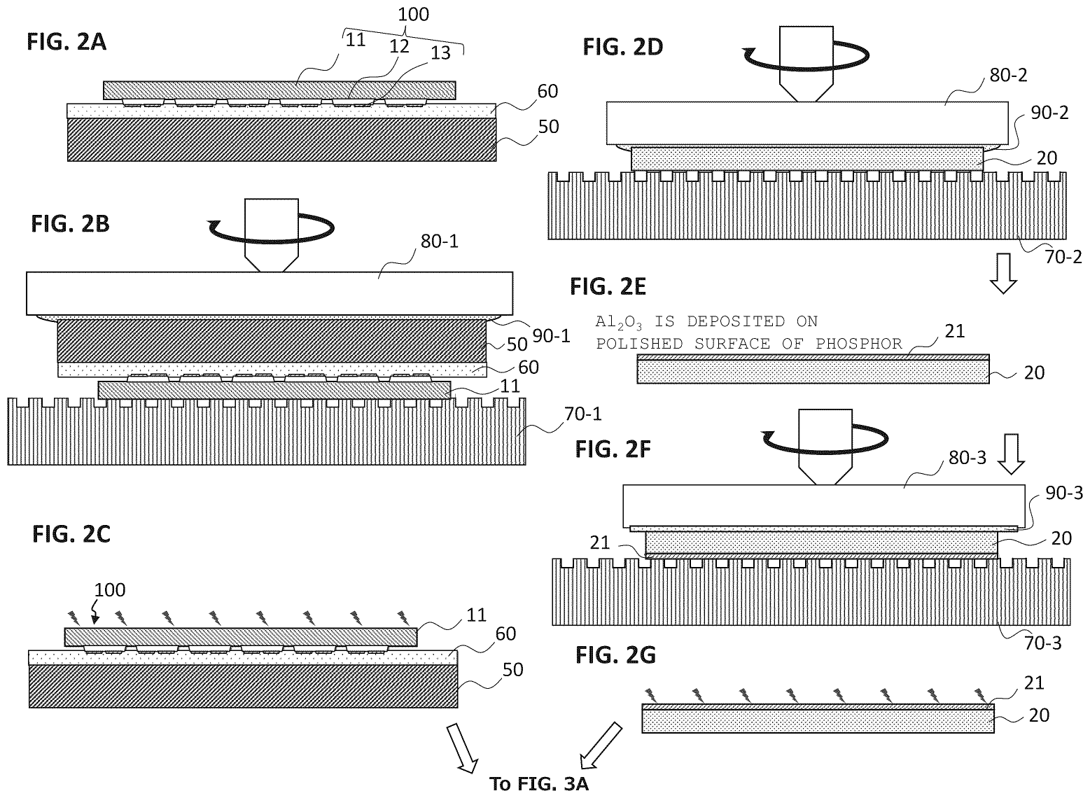

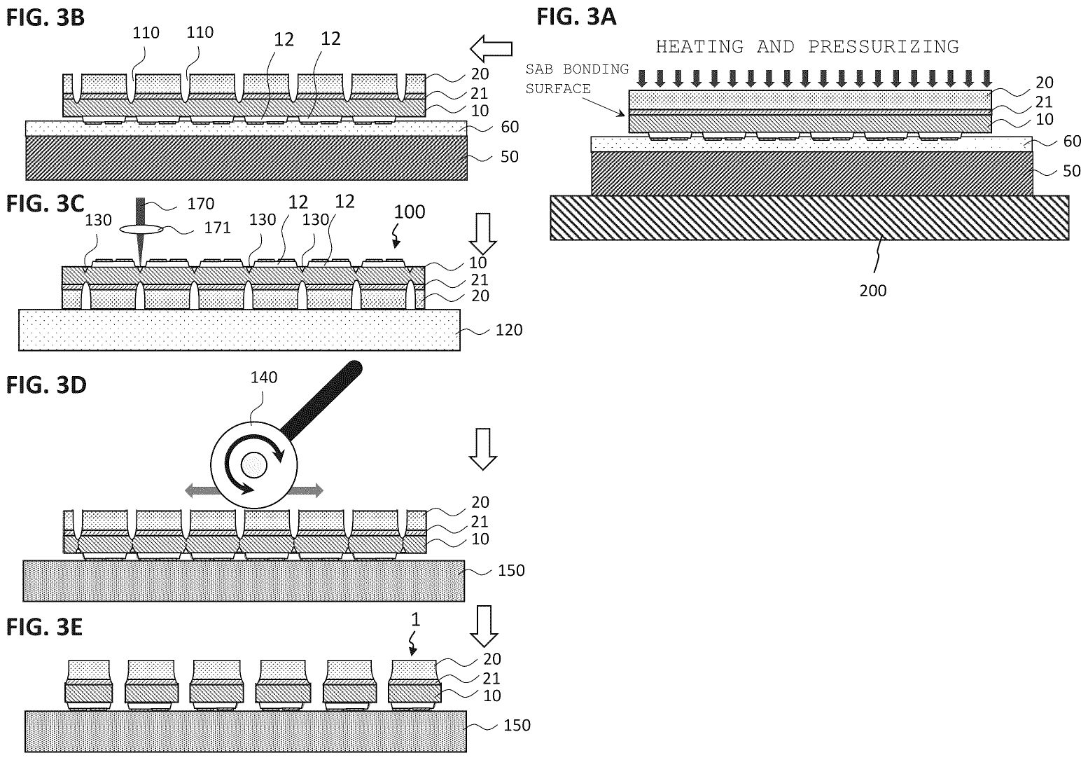

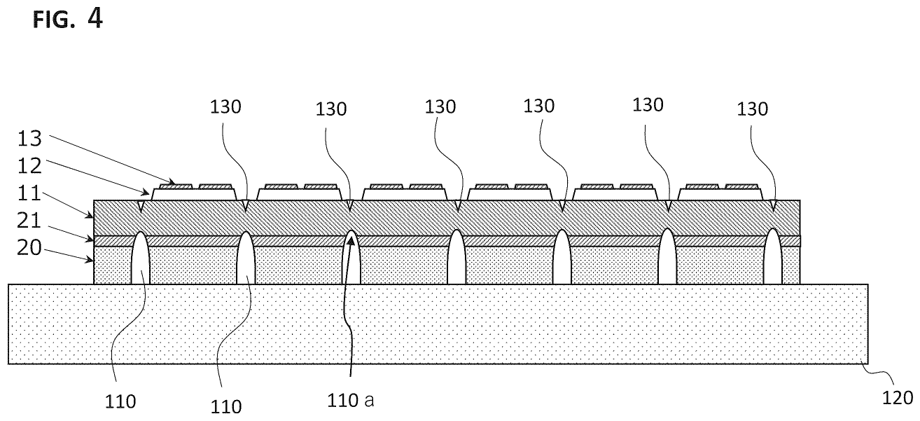

FIGS. 2A to 3E are diagrams illustrating a method of manufacturing a semiconductor light emitting device according to the embodiment. FIG. 4 is a sectional view illustrating a shape of a stacked body after the manufacturing step of FIG. 3C.

Each manufacturing step will be described with reference to FIGS. 2A to 4.

### Polishing Step for Light Emitting Element 10

First, as in FIG. 2A, a light emitting element plate 100 in which pluralities of semiconductor light emitting layers 12 and electrodes 13 are arranged at intervals in a main plane direction to be disposed on a lower surface of the continuous element substrate 11 is prepared. The intervals of the plurality of semiconductor light emitting layers 12 of the light emitting element plate 100 are designed so that the individual light emitting elements 10 are obtained by dividing the element substrate 11 at the boundaries of the neighboring light emitting elements 10.

As in FIG. 2A, a support substrate 50 is adhered to the plurality of arranged semiconductor light emitting layers 12 of the light emitting element plate 100 by a heat-resistant adhesive layer 60.

As in FIG. 2B, a rear surface (a surface opposite to the side to which the semiconductor light emitting layers 12 are adhered) of the support substrate 50 is fixed to a polishing stage 80-1 by an adhesive layer 90-1.

A polishing surface table 70-1 is prepared, and the rear surface of the element substrate 11 of the light emitting element plate 100 is cut and polished to be made thin using a slurry including diamond polishing particles by the polishing surface table 70-1, thereby flattening the surface of the element substrate 11 up to roughness (Ra) of a distance in which an intermolecular force acts (about 0.5 nm or less) or less.

Specifically, for example, a grinding step, a mechanical polishing step, and a CMP step are performed in order using the polishing surface table 70-1.

For example, in the grinding step, the thickness of the element substrate 11 (for example, 830 μm) is thinned up to 150 μm using a grindstone with grain size #230 by a grinding apparatus. The roughness (Ra) of the element substrate 11 after grinding is about 200 nm.

Subsequently, in the mechanical polishing step, first mechanical polishing is performed on the surface of the element substrate 11 with a thickness of 150 μm after the grinding step using a slurry including diamond polishing particles with a grain size of 6 μm so that the roughness (Ra) of the element substrate 11 becomes less than 50 nm. In the first mechanical polishing step, a flaw or crack layer of the surface caused by the polishing step can be removed. The thickness of the element substrate after the first mechanical polishing step becomes about 120 μm. Thereafter, second mechanical polishing is performed using a slurry including diamond polishing particles with a grain size of 1 μm so that the roughness (Ra) of the element substrate 11 becomes less than 10 nm.

Subsequently, in the CMP step, the CMP is performed using a slurry including diamond polishing particles with a grain size of 50 nm so that the roughness (Ra) of the element substrate 11 is reduced to less than 0.5 nm.

Through the steps, it is possible to flatten the surface of the element substrate 11 up to roughness (Ra) less than 0.5 nm that is a distance in which an intermolecular force acts (about 0.5 nm or less) or less.

Subsequently, as in FIG. 2C, the surface of the element substrate 11 after the polishing is subjected to ultraviolet (for example, excimer light) treatment and plasma treatment.

Specifically, the polished surface of the element substrate 11 is irradiated with ultraviolet (excimer light: wavelength (175±15) nm) and is cleaned.

Subsequently, the light emitting element plate 100 is disposed in a vacuum apparatus and plasma of a mixed gas of two or more of Ar, O₂, and N₂ is generated with high-frequency power (100 W to 450 W, preferably 250 W to 350 W), and plasma treatment is performed on the polished surface of the element substrate 11 for a predetermined processing time (1 minute to 10 minutes, preferably 3 minutes to 6 minutes) to activate the surface.

Accordingly, impurities on the surface of the element substrate 11 are removed and dangling bonds are generated. Thereafter, the element substrate 11 is exposed to the atmosphere to form a hydroxyl group (—OH) in the dangling bonds of the plasma-irradiated surface.

### Polishing Step of Phosphor Plate 20

On the other hand, as in FIG. 2D, the large phosphor plate 20 in which the phosphor plates 20 of the plurality of semiconductor light emitting devices 1 continue is prepared and is fixed to a polishing stage 80-2 by an adhesive layer 90-2.

A polishing surface table 70-2 is prepared and the surface of the phosphor plate 20 is polished using a slurry including diamond polishing particles by the polishing surface table 70-2.

Specifically, for example, the mechanical polishing step and the CMP step are performed in order using the polishing surface table 70-2.

In the mechanical polishing step, the surface of the phosphor plate 20 is mechanically polished using a slurry including diamond polishing particles with a grain size of 6 μm. After the mechanical polishing, the roughness (Ra) of the phosphor plate 20 becomes less than 10 nm by further performing the mechanical polishing using a slurry including diamond polishing particles with a grain size of 1 μm.

Subsequently, in the CMP step, the CMP is performed using a slurry including diamond polishing particles with a grain size of 50 nm, so that the roughness (Ra) of the phosphor plate is reduced to less than 1 nm. The CMP step is performed as necessary.

Thereafter, the polishing stage 80-2 is removed from the phosphor plate 20.

### Formation and Polishing of Buffer Layer 21

Next, as in FIG. 2E, the amorphous buffer layer 21 is formed on the polished surface of the phosphor plate 20.

Here, an amorphous aluminum oxide (Al₂O₃ or the like) film serving as the buffer layer 21 is formed on the polished surface of the phosphor plate 20 with a thickness of 600 nm by the EB evaporation method. Specifically, for example, an aluminum oxide (Al₂O₃ or the like) film is formed without heating or cooling the substrate (the phosphor plate 20) with a partial oxygen pressure of about 1×10⁻² Pa, for example, using deposition Al₂O₃ fine particles as a deposition source.

Subsequently, as in FIG. 2F, a polishing stage 80-3 is fixed to a surface opposite to the surface on which the buffer layer 21 of the phosphor plate 20 is formed by an adhesive layer 90-3.

A polishing surface table 70-3 is prepared and the surface of the buffer layer 21 of the phosphor plate 20 is polished by CMP with the polishing surface table 70-3 using a slurry including silica particles with a few nm to tens of nm, so that the roughness (Ra) becomes less than 0.5 nm. The roughness is roughness (Ra) of a distance in which an intermolecular force acts (about 0.5 nm or less) or less.

Subsequently, as in FIG. 2G, the polished surface of the phosphor plate 20 is subjected to ultraviolet (excimer light) treatment and plasma treatment to form dangling bonds, and then is exposed to the atmosphere to form a hydroxyl group (—OH) in the dangling bonds DB. Conditions of the processes are the same as those of FIG. 2C, and thus description thereof will be omitted.

The ultraviolet (excimer light) treatment and the plasma treatment of the element substrate 11 in FIG. 2C and the ultraviolet (excimer light) treatment and the plasma treatment of the phosphor plate 20 in FIG. 2G are preferably performed so as to be ended at the same time.

After the plasma treatment, the light emitting element 10 and the phosphor plate 20 are extracted from the vacuum apparatus.

### Bonding Step

Subsequently, as in FIG. 3A, the light emitting element plate 100 supported by the support substrate 50 is mounted on a heating and pressurizing table 200, and the phosphor plate 20 is mounted on the light emitting element plate 100. Here, the surface of the element substrate 11 of the light emitting element plate 100 subjected to the polishing, the ultraviolet (excimer light) treatment, and the plasma treatment is mounted to come into contact with the surface of the buffer layer 21 of the phosphor plate 20 subjected to the polishing, the ultraviolet (excimer light) treatment, and the plasma treatment. Accordingly, the surface of the element substrate 11 and the surface of the buffer layer 21 of the phosphor plate 20 are temporarily bonded by forming a hydrogen bond portion through hydrogen bonding between hydroxyl groups.

Subsequently, in the state of FIG. 3A, the light emitting element plate 100 and the phosphor plate 20 are heated under atmospheric pressure and temperature of 100° C. to 300° C. or preferably 150° C. to 250° C. by the heating and pressurizing table 200. The heating and pressurizing table 200 applies a load (for example, 2 MPa or more or preferably 10 MPa or more) to the light emitting element plate 100 and the phosphor plate 20. A heating and pressurizing state is kept for 30 minutes or more, preferably 2 hours or more, and the light emitting element plate 100 and the phosphor plate 20 are bonded by surface activated bonding.

The element substrate 11 and the phosphor plate 20 are bonded with the buffer layer 21 interposed therebetween by surface activated bonding to form a stacked body. Here, while the hydroxyl groups are thermally decomposed by heating and pressurizing and hydrogen atoms are expelled from the hydroxyl groups to form oxygen bonds, excessive hydroxyl groups turn into water or a hydrogen gas (H₂O, H₂) and are detached from the bonding interface.

The light emitting element plate 100 and the phosphor plate 20 may be disposed in the vacuum apparatus and be heated and pressurized to be bonded under a reduced pressure.

### Incision Forming Step

As in FIG. 3B, groove-shaped incisions 110 of a predetermined depth are formed at positions corresponding to gaps between the plurality of semiconductor light emitting layers from the phosphor plate 20 side of the stacked body.

The incisions 110 reach the buffer layer 21 and penetrate through the buffer layer 21. The incisions 110 penetrate through the bonding surface of the phosphor plate 20 and the light emitting element plate 100 and reach the element substrate 11.

Specifically, for example, the incisions 110 are formed by blade dicing using a blade with a blade width of 20 μm to 500 μm. The depth of the incisions 110 are formed beyond the phosphor plate 20 and the buffer layer 21 to penetrate by 1 μm to 50 μm or preferably 1 μm to 20 μm into the element substrate 11.

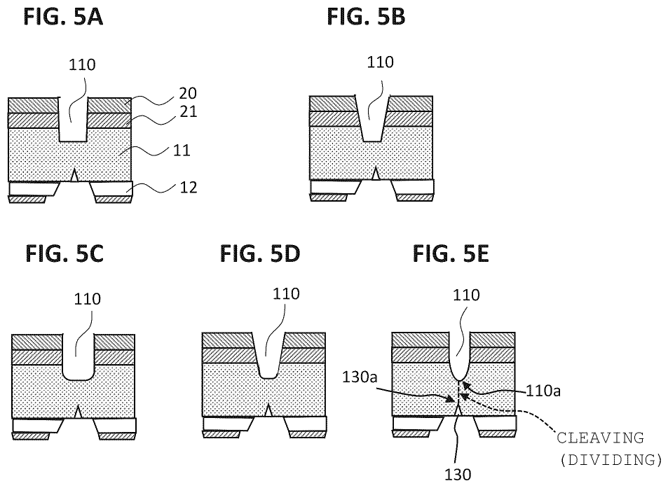

A cross-sectional shape of the incision 110 may be any one of a rectangle (FIG. 5A), a trapezoidal (FIG. 5B), a rectangle with rounded corners (FIG. 5C), a trapezoidal with rounded corners (FIG. 5D), and a parabola (FIG. 5E) as illustrated in FIGS. 5A to 5E, preferably a shape with rounded corners (FIGS. 5C to 5E), and particularly preferably a parabola (FIG. 5E).

The incision 110 with the parabolic cross-sectional shape (FIG. 5E) has a shape closest to the lower surface (a surface on which the semiconductor light emitting layer 12 is mounted) of the element substrate 11 at a single point of a tip end 110a of the incision cross section. Accordingly, in a segmentation step to be described below, stress can be focused on the single point of the tip of the tip end 110a by applying a force to the stacked body and the element substrate 11 can be divided by cleaving or the like by setting the position as a start point.

The incision 110 is formed by the blade dicing here, but can also be formed by laser dicing.

### Notch Forming Step

Subsequently, as in FIG. 3C, the support substrate 50 is detached from the semiconductor light emitting layer 12 and an adhesive sheet 120 is attached to the phosphor plate 20 side of the stacked body.

Groove-shaped notches 130 are formed in the element substrate 11 between the plurality of semiconductor light emitting layers 12 from the light emitting element plate 100 side of the stacked body.

Specifically, for example, a laser beam 170 is condensed with a lens 171 and is radiated to the element substrate 11 at a gap between the plurality of semiconductor light emitting layers 12 by a laser scribing apparatus to form the groove-shaped notches 130.

A sum of the depth of the notch 130 and the depth of the incision 110 is set to be shallower than the thickness of the stacked body. The stacked body is divided by cracking such as cleaving.

A protective film may be formed on the surface of the semiconductor light emitting layer by a coating method by the laser scribing apparatus before the notch 130 is formed. The protective film prevents pollution occurring due to laser scribing from being attached to the surface of the semiconductor light emitting layer. The protective film can be removed by water cleaning in a subsequent step.

As the laser beam 170, a nano-pulse or pico-pulse laser is preferably used. As a wavelength of the laser beam 170, a wavelength of 355 nm can be used.

A shape of the notch 130 is preferably a wedge shape and a width of the notch 130 is preferably 10 μm or less and particularly preferably 2 μm or less. A depth of the notch 130 is preferably 2 μm or more and particularly preferably 5 μm or more.

Accordingly, the stacked body becomes a shape of FIG. 4.

After the notch 130 is formed, the stacked body is subjected to water cleaning and organic cleaning to remove pollution due to the laser scribing.

In FIG. 3C, the laser beam 170 is radiated from the semiconductor light emitting layer 12 side, but the laser beam 170 can be radiated from the phosphor plate 20 side so that the notch 130 is formed at a position of the notch 130 of the element substrate 11 in FIG. 3C. For example, a cleaving surface can also be formed in the element substrate 11 by a stealth dicing apparatus.

Here, since the gap between the semiconductor light emitting layers 12 is narrow, the notch 130 is formed by the laser scribing. However, the notch 130 can also be provided by blade dicing using a thin blade.

### Segmentation Step

As in FIG. 3D, the surface of the light emitting element 10 of the stacked body is faced downward to be attached to an adhesive sheet 150.

When a roller 140 uniformly presses the entire surface of the phosphor plate 20 of the stacked body, the element substrate 11 between the tip end 110a of the incision 110 and a tip end 130a of the notch 130 (see FIG. 5E) is cleaved and split (see FIG. 5E). Accordingly, the semiconductor light emitting device 1 is segmented.

Because the element substrate 11 is curved by an increase in temperature by radiation of the laser beam, if conditions are appropriately set while the laser beam 170 is radiated in the step of FIG. 3C during forming of the notch 130, the element substrate 11 between the notch 130 and the incision 110 is cleaved and segmented just by radiating the laser beam 170 and forming the notch 130. Here, a step of adding a force with the roller 140 can be omitted.

### Step of Spacing Semiconductor Light Emitting Device 1

Finally, as in FIG. 3E, the interval between the semiconductor light emitting devices 1 on the adhesive sheet 150 is broadened by stretching (expanding) the adhesive sheet 150 in the main plane direction. Accordingly, the semiconductor light emitting device 1 can be handled.

As such, the semiconductor light emitting device 1 can be manufactured (refer to FIGS. 1A and 1B).

As described above, in the embodiment, by providing the buffer layer 21 and polishing the buffer layer 21, it is possible to bond the phosphor plate 20 to the light emitting device by the surface activated bonding without being affected by the fine crystal grains of the phosphor plate 20.

In the embodiment, by providing the incisions 110 at the depth reaching the buffer layer 21 in the stacked body in which the element substrate 11 of the light emitting element plate 100 and the phosphor plate are bonded by the surface activated bonding, it is possible to prevent peeling off from the bonding surface due to internal stress of the bonding surface or an external force. Since substrate dicing is not substantially performed after the penetration of the bonding surface in the dicing for providing the incisions 110 (about 5 μm to 20 μm), a dicing blade with a narrow width can be used. Therefore, it is possible to form the incision 110 having a small width provided between the light emitting elements.

By providing the notch 130 between the adjacent semiconductor light emitting layers, it is possible to easily divide the element substrate by cleaving or the like at a position connecting the notch 130 to the incision 110 with high accuracy. Accordingly, the phosphor plate and the element substrate can be divided accurately and the individual semiconductor light emitting device 1 can be segmented, and thus a manufacturing yield is improved.

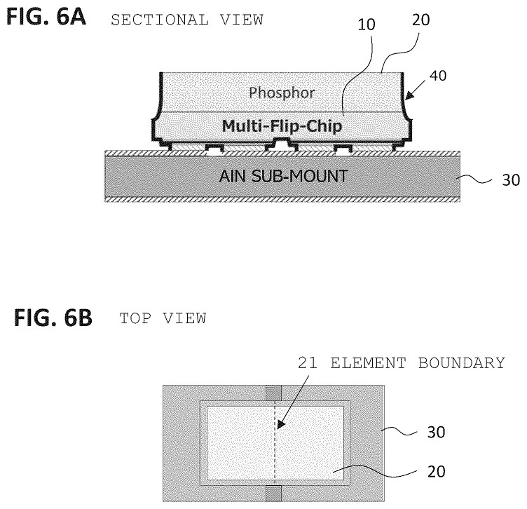

In the embodiment, as illustrated in FIGS. 1A and 1B, the semiconductor light emitting device including one pair of electrodes 13 is manufactured. However, as in FIGS. 6A and 6B, one semiconductor light emitting device including two pairs of electrodes 13 can be manufactured in the above-described steps.

### Evaluation

When a cross section of the buffer layer 21 of the manufactured semiconductor light emitting device was checked with a transmission electron microscope (TEM), neither crystal lattices nor crystal grains were observed, and it was confirmed that the buffer layer 21 was amorphous. Accordingly, it is assumed that the buffer layer 21 will not show a diffraction peak in an X-ray diffraction chart when X-ray diffraction is measured.

### Effects

In the semiconductor light emitting device according to the first embodiment, the bonding step for the phosphor plate 20 and the light emitting element 10 can be performed in the atmosphere by the surface activated bonding of FIG. 3A by disposing the amorphous buffer layer 21 between the phosphor plate 20 and the light emitting element 10.

By using the amorphous buffer layer 21, it is possible to set the roughness of the amorphous buffer layer 21 to 0.5 nm or less relatively easily even when a material used as the phosphor plate 20 is difficult to flatten up to the roughness (0.5 nm or less) at which the unevenness of the surface can be subjected to the surface activated bonding such as the composite ceramic phosphor plate. Therefore, the bonding can be performed by the surface activated bonding. Thus, it is possible to provide the semiconductor light emitting device with high reliability of the bonding surfaces by the surface activated bonding.

When Al₂O₃ is used as the material of the amorphous buffer layer 21, the refractive index and the thermal expansion coefficient are close to those of the element substrate 11 and the plate, the thermal phosphor conductivity is good when made to a thin film, and the Young's modulus is high and thus breakdown is difficult. Thus, it is possible to provide the semiconductor light emitting device that has high light extraction efficiency, has a high heat dissipation effect and is difficult to breakdown.

In particular, when aluminum oxide (Al₂O₃ or the like) is used as the material of the amorphous buffer layer 21, the sapphire substrate is used as the element substrate 11, and the composite ceramic phosphor plate (Al₂O₃/Ce:YAG) is used as the phosphor plate 20, the surface activated bonding can be performed stably by homogeneous bonding.

### Second Embodiment

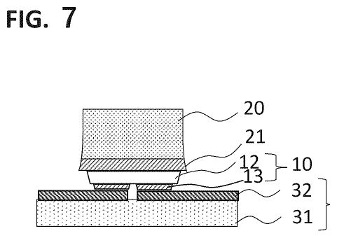

A semiconductor light emitting device according to a second embodiment will be described. As in FIG. 7, the semiconductor light emitting device according to the second embodiment does not include the element substrate 11, and the semiconductor light emitting layer 12 and the phosphor plate 20 are bonded with the buffer layer 21 interposed therebetween.

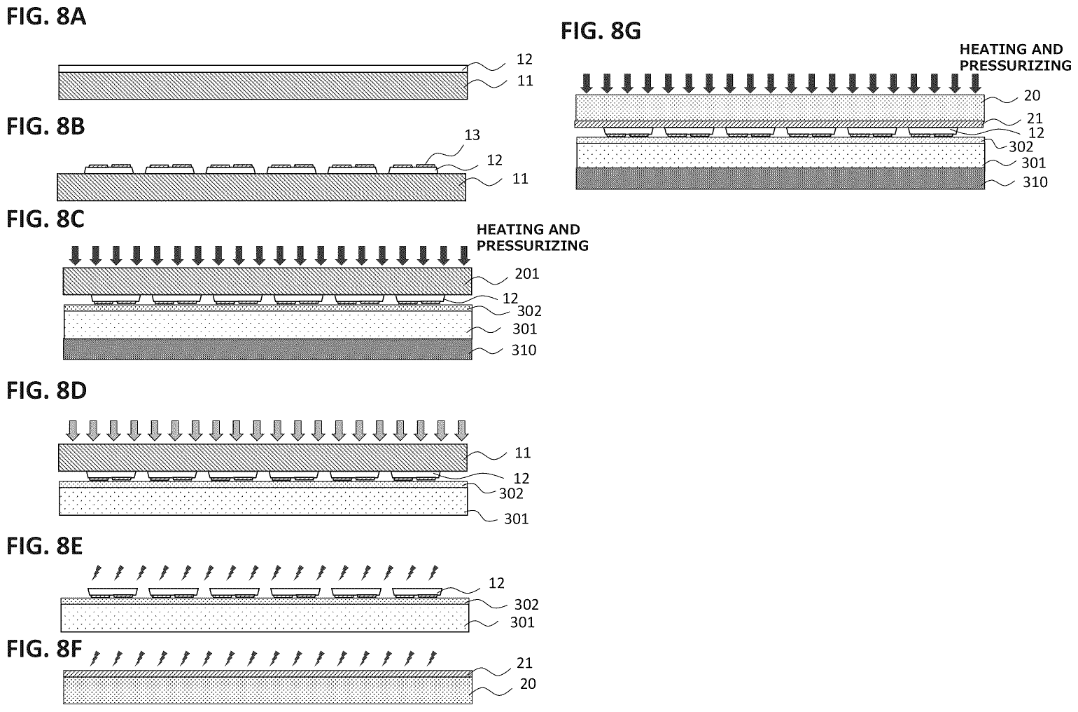

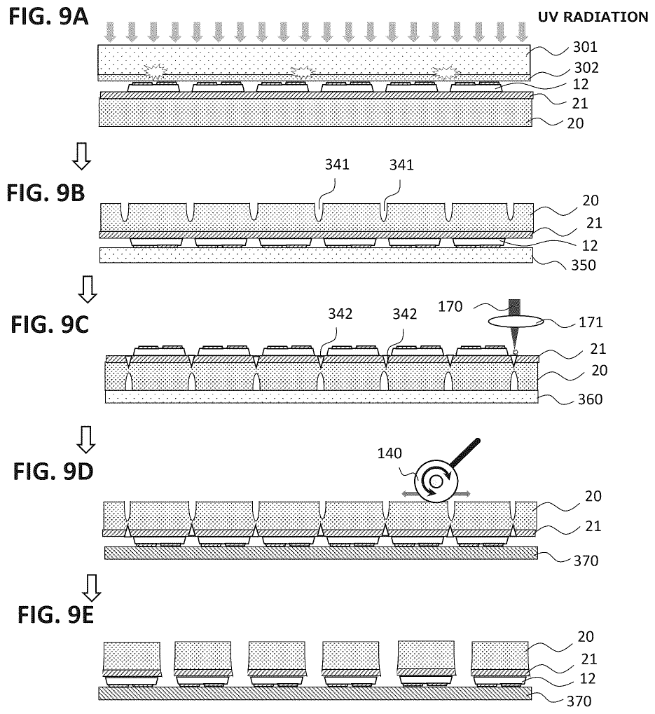

A method of manufacturing the semiconductor light emitting device according to the second embodiment will be described with reference to FIGS. 8A to 9E. In manufacturing steps of FIGS. 8A to 9E, similar manufacturing steps to FIGS. 2A to 3E will be described simply.

As in FIG. 8A, the light emitting element plate 100 in which the semiconductor light emitting layer 12 is formed on the front surface of the element substrate 11 is prepared.

As in FIG. 8B, the semiconductor light emitting layer 12 is processed by etching or the like in the shape of the semiconductor light emitting layer 12 for each individual semiconductor light emitting device. Thereafter, one pair of electrodes 13 are formed on the semiconductor light emitting layer 12.

As in FIG. 8C, the electrodes 13 of the semiconductor light emitting layer 12 are fixed onto a transparent support substrate 301 by an adhesive layer 302 formed of a resin adhesive. The support substrate 301 is mounted on a support table 310.

As in FIG. 8D, a laser beam such as excimer laser is radiated to the element substrate (sapphire substrate) 11 so that the element substrate 11 is removed by laser lift-off. Accordingly, as in FIG. 8E, the semiconductor light emitting layer 12 is exposed.

In FIG. 8E, the exposed semiconductor light emitting layer 12 is polished, subjected to surface flattening, and subjected to ultraviolet (for example, excimer light) treatment and plasma treatment. The polishing, the ultraviolet (for example, excimer light) treatment, and the plasma treatment are performed similarly to the steps of FIGS. 2A to 2C of the first embodiment.

In the step of FIG. 8F, the phosphor plate 20 is polished and the amorphous buffer layer 21 is formed on the polished surface of the phosphor plate 20. The surface of the buffer layer 21 is polished, and the ultraviolet (for example, excimer light) treatment and the plasma treatment are performed. The processes are performed similarly to the steps of FIGS. 2D to 2G of the first embodiment.

In the step of FIG. 8G, the phosphor plate 20 is mounted on the semiconductor light emitting layer 12 so that the buffer layer 21 comes into contact, and the surface activated bonding is performed on the semiconductor light emitting layer 12 and the phosphor plate 20 by heating and pressurizing. The step is performed similarly to the step of FIG. 3A of the first embodiment.

Subsequently, in the step of FIG. 9A, the support substrate 301 and the adhesive layer 302 are removed from the semiconductor light emitting layer 12 by radiating ultraviolet light and generating bubbles.

When the semiconductor light emitting layer 12 is mounted by the adhesive layer 302 formed of a metal material using a substrate of Si or the like as the support substrate 301, a sacrifice layer formed of silver is formed as an intermediate layer of the adhesive layer 302 and the sacrifice layer is dissolved by a nitric acid or the like, so that the support substrate 301 and the adhesive layer 302 can be removed.

In the step of FIG. 9B, an adhesive sheet 350 is attached to the semiconductor light emitting layer 12 side for support and incisions 341 are formed in the phosphor plate 20. The step is performed similarly to the step of FIG. 3B of the first embodiment. The depth of the incisions 341 does not reach the buffer layer 21 unlike the first embodiment.

In the step of FIG. 9C, the adhesive sheet 350 is removed and an adhesive sheet 360 is attached to the phosphor plate 20 side for support. The laser beam 170 is condensed with the lens 171 on the buffer layer 21 in the gaps between the plurality of semiconductor light emitting layers 12 by the laser scribing apparatus from the light emitting element plate 100 side of the stacked body to form groove-shaped notches 342. The step is performed similarly to the step of FIG. 3C of the first embodiment, but the notches 342 are formed directly on the buffer layer 21 unlike the first embodiment.

In the embodiment, the notches 342 are formed, but the notches can be formed arbitrarily as necessary since the buffer layer 21 is a thin film. That is, the notches 342 may not be provided.

The notches 342 can also be formed at tip ends of the incisions 341.

Thereafter, the adhesive sheet 360 is removed and an adhesive sheet 370 is attached again to the semiconductor light emitting layer 12 side for support. Steps of FIGS. 9D and 9E are performed similarly to the steps of FIGS. 3D and 3E to segment the individual semiconductor light emitting devices.

As such, according to the second embodiment, it is possible to bond the phosphor plate 20 by the surface activated bonding even in the light emitting element 10 from which the element substrate 11 is removed.

In the embodiment, since the notches 342 are provided in the buffer layer 21, it is possible to prevent stress from being applied to the light emitting element 10.

The other effects are similar to those of the first embodiment.

### Third Embodiment

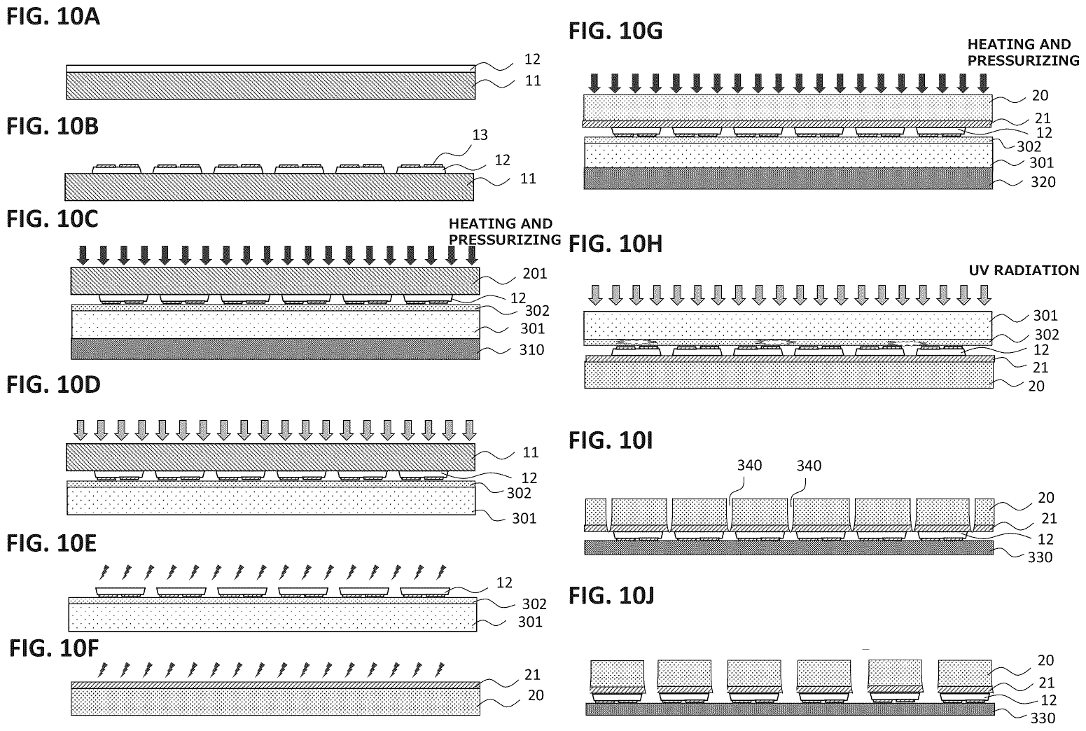

A semiconductor light emitting device according to a third embodiment will be described with reference to FIGS. 10A to 10J. The semiconductor light emitting device according to the third embodiment has a configuration similar to that of the semiconductor light emitting device according to the second embodiment illustrated in FIG. 7, but manufacturing steps are different from those of the second embodiment. In the second embodiment, in steps of FIGS. 9B to 9D, the incisions 341 and the notches 342 are formed to cleave the phosphor plate 20 and segment the semiconductor light emitting devices. In the third embodiment, however, the phosphor plate 20 is cut by dicing.

A method of manufacturing the semiconductor light emitting device according to the third embodiment will be described with reference to FIGS. 10A to 10J. In the manufacturing steps of FIGS. 10A to 10J, the manufacturing steps similar to those of FIGS. 8A to 9E will be described simply.

The steps of FIGS. 10A to 10H are performed similarly to the steps of FIGS. 8A to 8G and 9A. Accordingly, a stacked body in which the common phosphor plate 20 is bonded on the upper surface of the semiconductor light emitting layers 12 arranged at intervals with the buffer layer 21 interposed therebetween is formed.

Subsequently, in the step of FIG. 101, an adhesive sheet 330 is attached to the semiconductor light emitting layer 12 side to support the stacked body. The incisions 340 are formed from the phosphor plate 20 side by dicing and the phosphor plate 20 and the buffer layer 21 are cut. Accordingly, the semiconductor light emitting devices are segmented.

Finally, as in FIG. 10J, the adhesive sheet 330 is stretched (expanded) in the main plane direction so that the intervals of the semiconductor light emitting devices on the adhesive sheet 330 are broadened. Accordingly, the semiconductor light emitting devices can be handled.

As such, it is possible to manufacture the semiconductor light emitting device of FIG. 7.

In the manufacturing method according to the third embodiment, the phosphor plate 20 is cut by dicing. Therefore, compared to the cleaving method as in the second embodiment, it is preferable to arrange the semiconductor light emitting layers 12 at intervals broadened by gaps of the incisions 340 occurring due to the thickness of a dicing blade.

### Fourth Embodiment

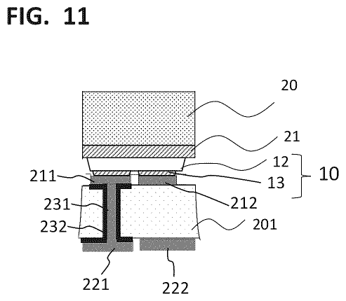

A semiconductor light emitting device according to a fourth embodiment will be described with reference to FIGS. 11 to 13I. The semiconductor light emitting device according to the fourth embodiment does not include the element substrate 11, as illustrated in FIG. 11, similarly to the semiconductor light emitting device of the second embodiment illustrated in FIG. 7, but unlike the second embodiment, includes a Si substrate 201 instead of the wiring substrate 30 that supplies electricity to the light emitting element 10.

The Si substrate 201 includes one pair of upper electrodes 211 and 212 on an upper surface and one pair of lower electrode 221 and 222 on a lower surface. One upper electrode 211 and one lower electrode 221 are connected by a through electrode 231 penetrating through a via provided in the Si substrate 201.

One pair of upper electrodes 211 and 212 are connected to one pair of electrodes 13 of the semiconductor light emitting element 10, respectively.

An insulating layer 232 is disposed at each of between the through electrode 231 and an inner wall of the via, between the lower surface of the upper electrode 211 and the Si substrate 201, and between the upper surface of the lower electrode 221 and the Si substrate 201. Accordingly, a current flows to the upper electrode 211 via the lower electrode 221 and the through electrode 231.

A current flows to the other upper electrode 212 via the other lower electrode 222 via the Si substrate 201.

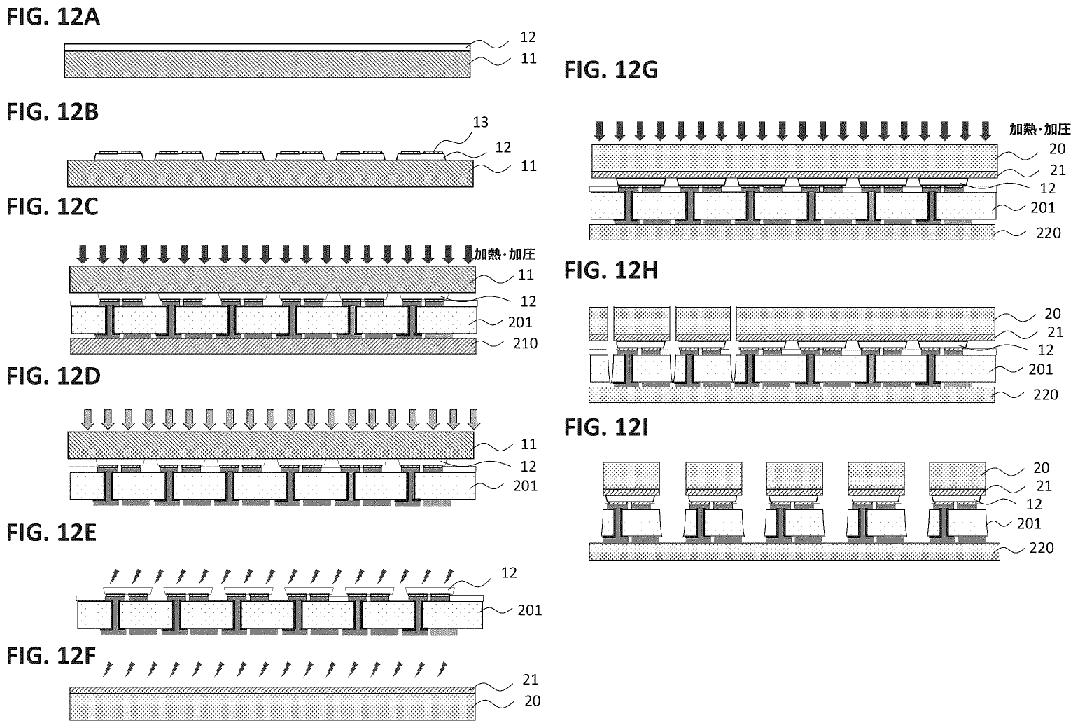

A method of manufacturing the semiconductor light emitting device according to the fourth embodiment will be described with reference to FIGS. 12A to 12I. In manufacturing steps of FIGS. 12A to 12I, similar manufacturing steps to FIGS. 8A to 9E will be described simply.

The steps of FIGS. 12A and 12B are performed similarly to FIGS. 8A and 8B. Accordingly, the plurality of semiconductor light emitting layers 12 are formed at a predetermined interval on the element substrate 11 and one pair of electrodes 13 are formed on the semiconductor light emitting layer 12.

In the step of FIG. 12C, the upper electrodes 211 and 212 of the Si substrate 201 that is prepared in advance and has the configuration of FIG. 11 are fixed to the electrodes 13 of the semiconductor light emitting layer 12 by inter-metal bonding using heating and pressurizing. The Si substrate 201 is mounted on a support table 210.

In the step of FIG. 12D, as in FIG. 8D, the element substrate 11 is removed by laser lift-off.

In the step of FIG. 12E, as in FIG. 8E, the semiconductor light emitting layer 12 is polished, subjected to surface flattening, and subjected to ultraviolet (for example, excimer light) treatment and plasma treatment.

In the step of FIG. 12F, as in FIG. 8F, the phosphor plate 20 is polished and the amorphous buffer layer 21 is formed on the polished surface. The surface of the buffer layer 21 is polished, and the ultraviolet (for example, excimer light) treatment and the plasma treatment are performed.

In the step of FIG. 12G, as in FIG. 8G, the phosphor plate 20 is mounted on the semiconductor light emitting layer 12 so that the buffer layer 21 comes into contact, and the surface activated bonding is performed on the semiconductor light emitting layer 12 and the phosphor plate 20 by heating and pressurizing. An adhesive sheet 220 is attached to the lower surface of the Si substrate 201.

Subsequently, in the step of FIG. 12H, the phosphor plate 20 is cut at a position between the light emitting devices 10 by dicing or laser dicing, and the cutting is performed further on to cut the Si substrate 201. Accordingly, the semiconductor light emitting devices are segmented.

Finally, as in FIG. 12I, the adhesive sheet 150 is stretched (expanded) in the main plane direction so that the intervals of the semiconductor light emitting devices 1 on the adhesive sheet 220 are broadened. Accordingly, the semiconductor light emitting devices can be handled.

As such, it is possible to manufacture the semiconductor light emitting device of FIG. 11.

In the manufacturing method of FIGS. 12A to 12I, the cutting is performed by cutting the phosphor plate 20 and the Si substrate 201 at once by dicing or laser dicing in the step of FIG. 12H, but the phosphor plate 20 and the Si substrate 201 may be cut separately. That is, instead of the step of FIG. 12H, steps of FIGS. 13H-1 and 13H-2 are performed.

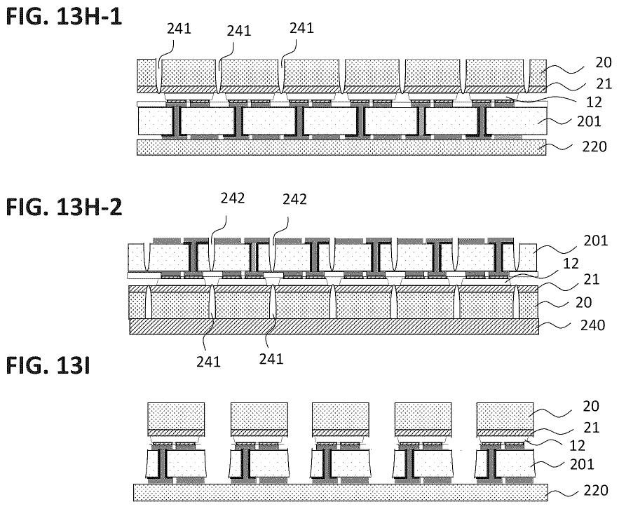

In the step of FIG. 13H-1, incisions 241 for cutting only the phosphor plate 20 are formed. An adhesive sheet 240 is attached to the upper surface of the phosphor plate 20 to support the phosphor plate 20.

Subsequently, in the step of FIG. 13H-2, the phosphor plate 20 is disposed downward and the adhesive sheet 220 of the Si substrate 201 is peeled off. Here, incisions 242 for cutting the Si substrate 201 by laser dicing are formed. Accordingly, the semiconductor light emitting devices are segmented. The adhesive sheet 220 is attached to the upper surface of the Si substrate 201 to support the Si substrate 201.

Finally, as in FIG. 13I, the adhesive sheet 240 is peeled off, and the adhesive sheet 220 is stretched (expanded) in the main plane direction so that the intervals of the semiconductor light emitting devices 1 on the adhesive sheet 220 are broadened. Accordingly, the semiconductor light emitting devices can be handled.

In the steps of FIGS. 13H-1 and 13H-2, an appropriate dicing blade or laser radiation conditions of laser dicing can be set to separately cut the phosphor plate 20 and the Si substrate 201.

The example in which dicing is used in the step of FIG. 13H-1 and laser dicing is used in the step of FIG. 13H-2 has been described. However, the dicing and the laser dicing may be reversed or both the phosphor plate 20 and the Si substrate 201 may be cut by the dicing and the laser dicing in different conditions.

The semiconductor light emitting device in FIG. 11 according to the fourth embodiment has a main element shape of a blue LED in which mass production steps are established like flip-chips, and the phosphor plate can be mounted at a wafer-level including the element shape that has no substrate via structure. Compared to a phosphor mounting structure in which an adhesive with bad thermal conductivity and a low refractive index is used, the semiconductor light emitting device in FIG. 11 can improve light extraction efficiency and heat dissipation of the phosphor can be enhanced.

The technique for the semiconductor light emitting device according to the embodiment can be used for a lighting fixture light source unit or a white light source module.

What is claimed is:

1. A semiconductor light emitting device comprising:
a light emitting element including a semiconductor light emitting layer; and
a phosphor plate bonded to the light emitting element, wherein
a buffer layer formed of a dielectric that transmits light emitted by the light emitting element is disposed between the light emitting element and the phosphor plate,
the light emitting element and the phosphor plate are bonded with the buffer layer interposed therebetween, and
the buffer layer is amorphous.

2. The semiconductor light emitting device according to claim 1, wherein the buffer layer does not show a diffraction peak in an X-ray diffraction chart when X-ray diffraction is measured.

3. The semiconductor light emitting device according to claim 1, wherein the buffer layer is one of an aluminum oxide layer, a niobium oxide layer, a zirconium oxide layer, a magnesium oxide layer, a silicon oxide layer, a titanium oxide layer, a tantalum oxide layer, and an yttrium oxide layer.

4. The semiconductor light emitting device according to claim 1, wherein the phosphor plate is bonded to the semiconductor light emitting layer with the buffer layer interposed therebetween.

5. The semiconductor light emitting device according to claim 1, wherein
the semiconductor light emitting layer is bonded to the phosphor plate with the buffer layer interposed therebetween,
the semiconductor light emitting layer includes a GaN layer, and
the buffer layer is an aluminum oxide layer.

6. The semiconductor light emitting device according to claim 1, wherein
the light emitting element includes an element substrate supporting the semiconductor light emitting layer,
the element substrate is bonded to the phosphor plate with the buffer layer interposed therebetween, and
the element substrate is sapphire and the buffer layer is an aluminum oxide layer.

7. The semiconductor light emitting device according to claim 5, wherein the phosphor plate is a composite ceramic phosphor plate in which phosphor particles are dispersed within a ceramic matrix of alumina.

8. A method of manufacturing a semiconductor light emitting device in which a phosphor plate that absorbs light emitted from a semiconductor light emitting layer and generating fluorescent light is bonded to a light emitting element including the semiconductor light emitting layer, the method comprising:
a light emitting element polishing step of polishing an upper surface of the light emitting element;
a phosphor polishing step of polishing a lower surface of the phosphor plate;
a forming step of forming an amorphous buffer layer formed of a dielectric material on at least one of the upper surface of the light emitting element and the lower surface of the phosphor plate; and
a bonding step of mounting the phosphor plate on the light emitting element such that the upper surface of the light emitting element and the lower surface of the phosphor plate face each other and performing heating and pressurizing to bond the phosphor plate onto the light emitting element.

9. The method of manufacturing a semiconductor light emitting device according to claim 8, wherein, in the forming step, the amorphous buffer layer is formed by a deposition method of heating a deposition source with an electron beam.

10. The method of manufacturing a semiconductor light emitting device according to claim 8, wherein
in the light emitting element polishing step, a plurality of the light emitting elements are arranged on a supporter at intervals in a main plane direction and upper surfaces of a plurality of arranged light emitting elements are polished, and
in the bonding step, the phosphor plate that is common is mounted on the plurality of arranged light emitting elements and the upper surfaces of the light emitting elements are bonded on the lower surface of the phosphor plate with the buffer layer interposed therebetween.

11. The method of manufacturing a semiconductor light emitting device according to claim 8, wherein
in the light emitting element polishing step, the light emitting element is disposed so that a plurality of semiconductor light emitting layers are arranged on a lower surface of an element substrate that is common, and an upper surface of the element substrate that is common is polished, and
in the bonding step, the upper surface of the element substrate is bonded to the lower surface of the phosphor plate with the buffer layer interposed therebetween.

12. The method of manufacturing a semiconductor light emitting device according to claim 10, the method further comprising:
a segmentation step of cutting or cleaving the phosphor plate at positions between the plurality of arranged light emitting elements after the bonding step.

13. The method of manufacturing a semiconductor light emitting device according to claim 11, the method further comprising:
a segmentation step of cutting or cleaving the phosphor plate and the element substrate at positions between the plurality of arranged light emitting elements after the bonding step.
